(19) United States
(12) Patent Application Publication
(10) Pub. No.: US 2008/0018201 A1
(43) Pub. Date: Jan. 24, 2008

(54) TOUCH PANEL

(75) Inventor: Kenichi MATSUMOTO, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/751,190

(22) Filed: May 21, 2007

(30) Foreign Application Priority Data
Jul. 19, 2006 (JP) JP 2006-196357

(51) Int. Cl. H02N 2/18; H01L 41/22

(52) U.S. Cl. 310/319; 29/25.35

(57) ABSTRACT

A touch panel that sandwiches a light transmitting piezoelectric material, which generates a voltage by a pressing force, between an upper conductive layer formed on a bottom face of an upper substrate and a lower conductive layer formed on a top face of a lower substrate. Since there is no space between the upper conductive layer and the lower conductive layer, reflection of external light can be reduced. This achieves good viewability. In addition, the touch panel can be easily manufactureable just by sequentially superimposing and attaching components

### FIELD OF THE INVENTION

The present invention relates to touch panels for typically operating a range of electronic devices.

### BACKGROUND OF THE INVENTION

With electronic devices such as mobile phones and car navigation systems becoming increasingly sophisticated and diversified, many products are adopting a light transmitting touch panel on a front face of a display device, typically a liquid crystal display. The user of the electronic device views what is displayed on the display device on a rear face of the touch panel through this touch panel, and presses the touch panel typically with a finger or pen. Increasingly more electronic devices are adopting the touch panel for switching functions. Accordingly, the user demands a touch panel with good viewability and reliable operation.

A conventional touch panel is described next with reference to FIG. 3.

In FIG. 3, dimensions in a thickness direction are enlarged for easier understanding of a structure.

FIG. 3 is a sectional view of the conventional touch panel. In FIG. 3, the touch panel includes light transmitting upper substrate 1, light transmitting lower substrate 2, upper conductive layer 3, lower conductive layer 4, and spacer 5. Light transmitting upper substrate 1 and light transmitting lower substrate 2 are light transmittable films. Upper conductive layer 3 is disposed on a bottom face of light transmitting upper substrate 1, and is made typically of indium tin oxide. In the same way, lower conductive layer 4 is formed on a top face of light transmitting lower substrate 2.

Dot spacers (not illustrated) are formed, using insulating resin, at predetermined intervals on a top face of lower conductive layer 4. A pair of top electrodes (not illustrated) are formed on both ends of upper conductive layer 3. A pair of bottom electrodes (not illustrated) are formed on both ends of lower conductive layer 4 in a direction perpendicular to the top electrodes.

Frame-like spacer 5 is formed on a periphery of the bottom face of light transmitting upper substrate 1 and a periphery of the top face of light transmitting lower substrate 2. An adhesive layer (not illustrated) is applied to top and bottom faces of this spacer 5, and attaches upper conductive layer 3 and lower conductive layer 4 by their peripheries. Accordingly, the touch panel is configured such that upper conductive layer 3 and lower conductive layer 4 face each other with a predetermined space in between.

A touch panel as configured above is disposed on a front face of typically a liquid crystal display device, and then mounted on an electronic device. Pairs of top electrodes and bottom electrodes are coupled to electronic circuitry (not illustrated) of the electronic device.

In the above structure, a top face of light transmitting upper substrate 1 is pressed typically by a finger or pen while the user views what is displayed on the liquid crystal display device on a rear face of the touch panel. A pressing operation makes light transmitting upper substrate 1 dent, and upper conductive layer 3 and lower conductive layer 4 come into local contact at a portion pressed.

Then, the electronic circuitry applies a voltage sequentially to the top electrodes and the bottom electrodes. The electronic circuitry detects a portion pressed based on a voltage difference between these electrodes. This switches between various functions of the electronic device.

However, in the touch panel in which a predetermined space is formed between upper conductive layer 3 and lower conductive layer 4, external light such as sunlight or lamplight reflects on the top and bottom faces of the space where refractive index is particularly large. As a result, a fringe pattern of light, a so-called Newton ring, is generated, and the liquid crystal display device on the rear face of the touch panel may become poorly visible

Accordingly, an idea to form a conductive layer on the top and bottom faces of a piezoelectric material, which generates a voltage by a pressing force, has been proposed. This eliminates the space, and thus reflection of the external light can be reduced. However, a heat of about 100 to 200° C. is applied to those using the piezoelectric material at forming the conductive layer on the top and bottom faces of the piezoelectric material such as by sputtering or deposition, and at printing and drying an insulating resin layer on its top and bottom faces. This makes manufacturing difficult, and may also degrade the piezoelectric material.

One example of related prior arts is Japanese Patent Unexamined Publication No. 2005-141547.

### SUMMARY OF THE INVENTION

A touch panel includes a light transmitting upper substrate where an upper conductive layer is formed on its bottom face, a light transmitting lower substrate where a lower conductive layer is formed on its top face, and a light transmitting piezoelectric material which generates a voltage in a thickness direction by a pressing force. The piezoelectric material is sandwiched between the upper conductive layer and the lower conductive layer. An adhesive layer attaches the upper conductive layer and the lower conductive layer.

A method of manufacturing the touch panel includes the steps of giving piezoelectricity in the thickness direction by applying an electric field to top and bottom faces of a polyvinylidene-fluoride film while stretching this film; fabricating a sheet of piezoelectric material sheet by cutting the polyvinylidene-fluoride film to which piezoelectricity is given; forming a thin film of indium-tin oxide or a tin oxide on a film of polyethylene telephthalate or polycarbonate, or glass; fabricating an upper substrate and s lower substrate by cutting one of the indium tin oxide and tin oxide on one of a polyethylene terephthalate film, polycarbonate film, and glass, and forming the upper conductive layer on the upper substrate and the lower conductive layer on the lower substrate; and holding the piezoelectric material by sandwiching the piezoelectric material between the upper conductive layer and the lower conductive layer.

### BRIEF DESCRIPTION OF THE DRAWINGS

FIG. 1 is a sectional view of a touch panel in accordance with an exemplary embodiment of the present invention.

FIG. 2 is an exploded perspective view of the touch panel in accordance with the exemplary embodiment of the present invention.

FIG. 3 is a sectional view of a conventional touch panel.

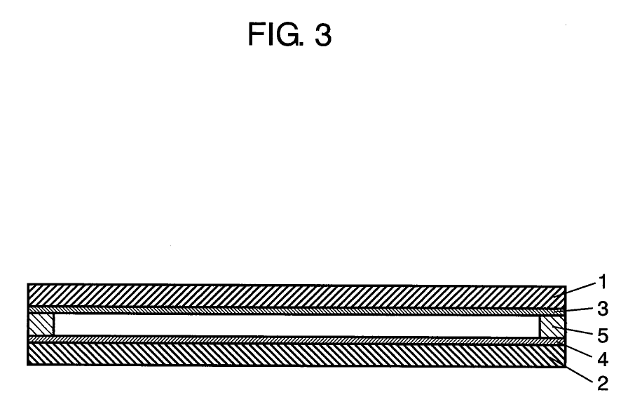

### DETAILED DESCRIPTION OF THE EXEMPLARY EMBODIMENTS

The present invention solves the above disadvantage of the prior art, and offers an easily-manufactureable touch panel with good viewability.

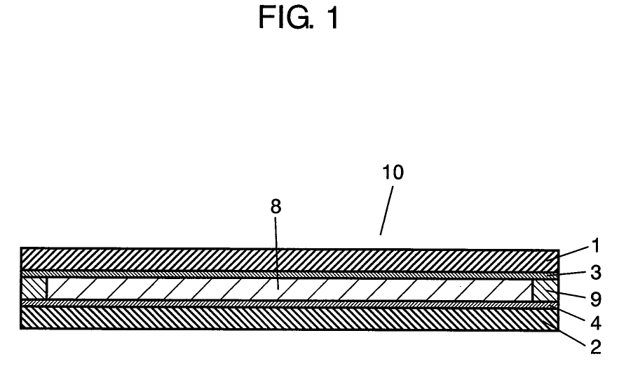

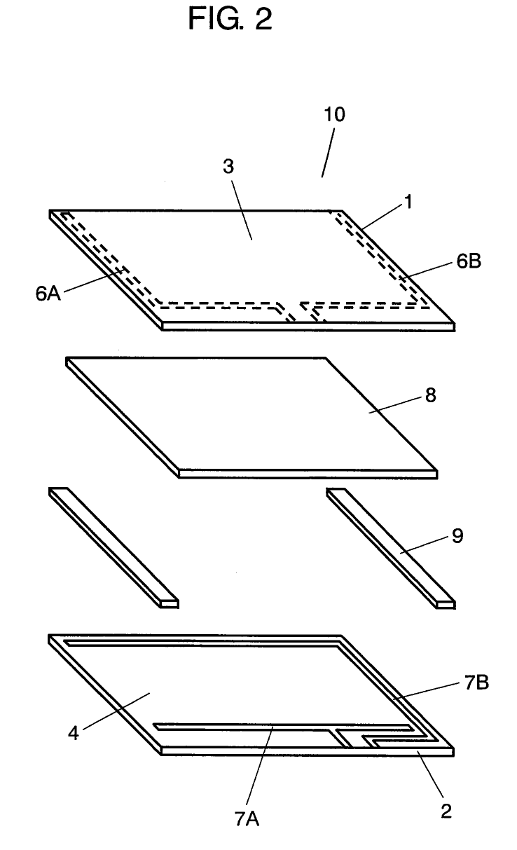

An exemplary embodiment of the present invention is described below with reference to FIGS. 1 and 2.

Dimensions in a thickness direction are enlarged in FIGS. 1 and 2 for easier understanding of a structure.

Components which have the same structure as that described in the Background Art are given the same reference marks, and thus their detailed description is omitted below.

### Embodiment

FIG. 1 is a sectional view and FIG. 2 is an exploded perspective view of a touch panel in an embodiment of the present invention. In FIGS. 1 and 2, touch panel 10 includes light transmitting upper substrate 1, light transmitting lower substrate 2, upper conductive layer 3, lower conductive layer 4, piezoelectric material 8, and adhesive layer 9.

Light transmitting upper substrate 1 is a light transmitting film made typically of polyethylene terephthalate or polycarbonate. Light transmitting lower substrate 2 is also light transmittable, and is made typically of polycarbonate, glass, or acryl. Light transmitting upper conductive layer 3 made typically of indium tin oxide or tin oxide is formed on a bottom face of light transmitting upper substrate 1, and lower conductive layer 4 is formed on a top face of light transmitting lower substrate 2 in the same way, such as by sputtering.

A pair of top electrodes 6A and 6B, made typically of silver or carbon, are formed on both ends of upper conductive layer 3. A pair of bottom electrodes 7A and 7B are formed on both ends of lower conductive layer 4 in a direction perpendicular to top electrodes 6A and 6B. These top electrodes 6A and 6B and bottom electrodes 7A and 7B are extended along the peripheries of upper conductive layer 3 and lower conductive layer 4 to the ends, respectively.

Piezoelectric material 8 is light transmittable, and is made of polyvinylidene-fluoride of a thickness of around 50 to 100 μm, and is light transmittable. When piezoelectric material 8 is pressed, a voltage is generated in the thickness direction of piezoelectric material 8. This piezoelectric material 8 is sandwiched between upper conductive layer 3 and lower conductive layer 4.

Adhesive layer 9 is typically acryl or rubber, and is printed on both ends of the bottom face of upper conductive layer 3 or the top face of lower conductive layer 4. Adhesive layer 9 attaches light transmitting upper substrate 1 and light transmitting lower substrate 2 so as to hold piezoelectric material 8 in between. This configures touch panel 10.

Next, a method of manufacturing touch panel 10 as configured above is described.

First, an electric field is applied to a strip of polyvinylidene-fluoride film while the strip is stretched in a predetermined direction so as to give piezoelectricity. Then, this film is cut into a predetermined dimension to fabricate a sheet of piezoelectric material 8.

A thin film of indium tin oxide or tin oxide, for example, is formed on one face of a strip of polyethylene terephthalate or polycarbonate film, or glass by sputtering or deposition. This is cut into a predetermined dimension, and adhesive layer 9 is printed to fabricate light transmitting upper substrate 1 and light transmitting lower substrate 2 on which upper conductive layer 3 and lower conductive layer 4 are formed, respectively.

Then, piezoelectric material 8 is sandwiched between these upper conductive layer 3 and lower conductive layer 4, and upper conductive layer 3 and lower conductive layer 4 are attached by adhesive layer 9. This completes the touch panel 10 in which piezoelectric material 8 is held.

In other words, piezoelectric material 8, light transmitting upper substrate 1, and light transmitting lower substrate 2 are fabricated separately, and at last, they are superimposed sequentially so as to complete the touch panel 10. Accordingly, piezoelectric material 8 is not exposed to heat used for sputtering or deposition, or for drying printed adhesive layer 9. Degradation of piezoelectric performance of piezoelectric material 8 can thus be prevented, and manufacturing processes also become simple.

Touch panel 10 as configured above is disposed on a front face of typically a liquid crystal display device, and then mounted on an electronic device. Then, top electrodes 6A and 6B and bottom electrodes 7A and 7B extended to the ends of light transmitting upper substrate 1 and light transmitting lower substrate 2, respectively, are coupled to electronic circuitry (not illustrated) of the electronic device.

In the above configuration, the user presses the top face of light transmitting upper substrate 1 at the front typically with a finger or pen, in accordance with a required operation displayed on the liquid crystal display device on a rear face of touch panel 10. This pressing force makes light transmitting upper substrate 1 dent and press piezoelectric material 8. A portion pressed on this piezoelectric material 8 then becomes compressed, and generates a several voltages in the thickness direction.

At this point, a voltage of around 5V is sequentially applied from the electronic circuitry of the electronic device to between top electrodes 6A and 6B at both ends of upper conductive layer 3, and between bottom electrodes 7A and 7B at both ends of lower conductive layer 4. The electronic circuitry detects a portion pressed in a horizontal direction based on a voltage difference between top electrodes 6A and 6B, and detects the portion pressed in a vertical direction based on a voltage difference between bottom electrodes 7A and 7B.

In other words, the electronic circuitry sequentially applies a voltage between top electrodes 6A and 6B, and between bottom electrodes 7A and 7B. Also based on a voltage difference of voltage generated in piezoelectric material 8 by the user's pressing operation, the electronic circuitry detects the portion pressed in the horizontal and vertical directions. Various functions of the electronic device are switched based on this detection result.

Since piezoelectric material 8 is sandwiched between upper conductive layer 3 on the bottom face of light transmitting upper substrate 1 and lower conductive layer 4 on the top face of light transmitting lower substrate 2, there is no space between the conductive layers. Accordingly, reflection of external light such as sunlight and lamplight is reduced, and thus a fringe pattern of light, a so-called Newton ring, or the like is unlikely generated. This ensures good viewability of the liquid crystal display device on the rear face of the touch panel.

Still more, the use of polyvinylidene-fluoride as piezoelectric material 8 makes piezoelectric material 8 relatively easy to manufacture, as already mentioned above. In addition, its good piezoelectric characteristic ensures electrically-reliable operation.

As described above, touch panel 10 is configured by sandwiching light transmitting piezoelectric material 8, where a voltage is generated in the thickness direction by the pressing force, between upper conductive layer 3 formed on the bottom face of light transmitting upper substrate 1 and lower conductive layer 4 formed on the top face of light transmitting lower substrate 2 in this embodiment. This structure eliminates the space between upper conductive layer 3 and lower conductive layer 2, reducing reflection of external light and thus gaining good viewability. In addition, an easily-manufactureable touch panel 10 can be achieved by simply superimposing and attaching components.

The use of polyvinylidene-fluoride for piezoelectric material 8 achieves satisfactory piezoelectric characteristic, and thus ensures reliable operation. This also facilitates fabrication of piezoelectric material 8.

The above description refers to the structure of forming upper conductive layer 3 or lower conductive layer 4 on the entire bottom face of light transmitting upper substrate 1 or the entire top face of 1 light transmitting lower substrate 2. However, the present invention is also applicable to a structure of forming lines of upper conductive layer 3 and lower conductive layer 4 perpendicular to each other and coupling comb-like ends of these conductive layers to top electrodes 6A and 6B and bottom electrodes 7A and 7B, respectively.

It is apparent from the above description that touch panel 10 of the present invention has advantages of good viewability and easy-fabrication. The present invention is thus effectively applicable to the operation of a range of electronic devices.

What is claimed is:

1. A touch panel comprising:
a light transmitting upper substrate where an upper conductive layer is formed on its bottom face;
a light transmitting lower substrate where a lower conductive layer is formed on its top face; and
a light transmitting piezoelectric material in which a voltage is generated in a thickness direction by a pressing force,
wherein the light transmitting piezoelectric material is sandwiched between the upper conductive layer and the lower conductive layer.

2. The touch panel of claim 1, wherein the light transmitting piezoelectric material is made of polyvinylidene-fluoride.

3. A manufacturing method of a touch panel, comprising:
giving piezoelectricity in a thickness direction to a polyvinylidene-fluoride film by applying an electric field to top and bottom faces of the film while stretching the film;
fabricating a sheet of piezoelectric material by cutting the polyvinylidene-fluoride film to which piezoelectricity is given;
forming a thin film of one of indium tin oxide and tin oxide on one of a polyethylene terephthalate film, polycarbonate film, and glass;
fabricating a upper substrate and a lower substrate by cutting one of the indium tin oxide and tin oxide on one of a polyethylene terephthalate film, polycarbonate film, and glass, forming an upper conductive layer on the top substrate, and forming a lower conductive layer on the bottom substrate; and
holding the piezoelectric material by sandwiching the piezoelectric material between the upper conductive layer and the lower conductive layer.
